(19) United States
(12) Patent Application Publication
(10) Pub. No.: US 2017/0025402 A1
(43) Pub. Date: Jan. 26, 2017

(54) SEMICONDUCTOR ESD PROTECTION CIRCUIT

(71) Applicant: TEXAS INSTRUMENTS INCORPORATED, DALLAS, TX (US)

(72) Inventors: CHRISTOPHER A. OPOCZYNSKI, DALLAS, TX (US); DENING WANG, MCKINNEY, TX (US)

(21) Appl. No.: 15/061,461

(22) Filed: Mar. 4, 2016

Related U.S. Application Data
(60) Provisional application No. 62/129,559, filed on Mar. 6, 2015.
(60) Provisional application No. 62/193,976, filed on Jul. 17, 2015.

(51) Int. Cl. H01L 27/02; H01L 29/06; H01L 21/762; H01L 29/36; H01L 29/66; H01L 29/866; H01L 23/535

(52) U.S. Cl. CPC H01L 27/0255; H01L 29/866; H01L 27/0292; H01L 29/0684; H01L 29/0649; H01L 23/535; H01L 29/36; H01L 29/66106; H01L 21/76224

(57) ABSTRACT

A semiconductor device includes a Zener diode having an anode layer and a cathode layer. The Zener diode provides an electrostatic discharge (ESD) path for ESD signals. At least two channel diodes are coupled to the ESD path of the Zener diode. Each of the channel diodes includes a common cathode layer and a separate anode region. The common cathode layer of the channel diodes is disposed on the cathode layer of the Zener diode. At least two channels are provided where each channel is coupled to one of the separate anode regions to provide an electrical connection for protected signal paths to the ESD path.

### CROSS-REFERENCE TO RELATED APPLICATION

This application claims the benefit of U.S. Provisional Patent Application 62/129,559, filed on Mar. 6, 2015, and entitled A COMPACT VERTICAL ESD TECHNOLOGY WITH MULTIPLE-CHANNELS SHARING ONE ZENER. This application also claims the benefit of U.S. Provisional Patent Application 62/193,976 filed on Jul. 17, 2015, and entitled A COMPACT VERTICAL ESD TECHNOLOGY WITH MULTIPLE-CHANNELS SHARING ONE ZENER. The entirety of both of which are incorporated by reference herein.

### TECHNICAL FIELD

This disclosure relates to electrostatic discharge (ESD) protection circuits and more particularly to a layered semiconductor structure where multiple ESD protection channels share a common Zener device.

### BACKGROUND

Many electronic components, such as microchips, can be damaged by electrostatic discharge (ESD). Sensitive components need to be protected during and after manufacture, during shipping and device assembly, and in the finished device. Various transient protection devices are available. For example, system-level ESD protection can be implemented using discrete diodes or capacitors. However, in many applications, discrete solutions consume board space, complicate layout, and/or compromise signal integrity at high data rates.

### SUMMARY

This disclosure relates to a layered semiconductor structure where multiple electrostatic discharge (ESD) protection channels share a common Zener device.

In one example, a semiconductor device includes a Zener diode having an anode layer and a cathode layer. The Zener diode provides an electrostatic discharge (ESD) path for ESD signals. At least two channel diodes are coupled to the ESD path of the Zener diode. Each of the channel diodes includes a common cathode layer and a separate anode region. The common cathode layer of the channel diodes is disposed on the cathode layer of the Zener diode. At least two channels are provided where each channel is coupled to one of the separate anode regions to provide an electrical connection for protected signal paths to the ESD path.

In another example, a semiconductor device includes a Zener diode having a P substrate layer and an N buried layer (NBL) disposed on the P substrate layer. The Zener diode provides an electrostatic discharge (ESD) path for ESD signals. At least two channel diodes couple the ESD signals to the ESD path of the Zener diode. The channel diodes include a common N-epitaxial (NEPI) layer and a separate P-well region for each of the channel diodes. The common NEPI layer of the channel diodes disposed on the NBL of the Zener diode. At least two channels are provided where each channel coupled to the P-well region of one of the channel diodes to provide an electrical connection for protected signal paths to the ESD path.

In yet another example, a method includes forming a P substrate layer. The method includes disposing an N-buried layer (NBL) on the P substrate layer to form a Zener diode in which the P substrate layer is an anode layer and the NBL is a cathode layer. The method includes forming an N-epitaxial (NEPI) layer on the NBL. This includes forming at least two P-well regions in the NEPI layer to provide at least two channel diodes in which the NEPI layer provides a common cathode layer for each of the channel diodes. The method includes forming a separate N-well region in the NEPI layer to provide at least one discharge diode that includes the N-well region and the P substrate layer. The method includes forming an isolation trench through the NEPI layer and the NBL between the channel diodes and the discharge diodes.

### BRIEF DESCRIPTION OF THE DRAWINGS

FIG. 1 illustrates an example block diagram of a semiconductor device having a vertical layer Zener structure that is shared by at least two protection channels and provides electrostatic discharge protection for a circuit.

FIG. 2 illustrates an example block diagram of a top view of a semiconductor device having a vertical layer Zener structure that is shared by four protection channels and provides electrostatic discharge protection for a circuit.

FIG. 3 illustrates an example block diagram of a side view of a semiconductor device having a vertical layer Zener structure that is shared by four protection channels and provides electrostatic discharge protection for a circuit.

FIG. 4 illustrates an example schematic diagram of an ESD protection device having a vertical layer Zener structure to provide electrostatic discharge protection for a circuit.

FIG. 5 illustrates an example schematic diagram of a semiconductor device having a vertical layer Zener structure to provide electrostatic discharge protection for a bus communications circuit.

FIG. 6 illustrates an example semiconductor device structure having a vertical layer Zener structure that is shared by four protection channels and provides electrostatic discharge protection for a circuit.

FIGS. 7-13 illustrate an example method for manufacturing the semiconductor device of FIG. 6.

### DETAILED DESCRIPTION

This disclosure relates to a layered semiconductor structure where multiple electrostatic discharge (ESD) protection channels share a common Zener device. A semiconductor device includes a Zener diode having an anode layer and a cathode layer. The anode layer can be formed as a P substrate layer in the semiconductor device and the cathode layer can be formed on the P substrate layer as an N buried layer (NBL). The Zener diode provides an electrostatic discharge (ESD) path for ESD signals appearing on protected signal paths coupled to the semiconductor device via respective input channels coupled to each of the channel diodes. The protected signal paths can be coupled to external circuits to provide ESD protection. More than one ESD signal carrying channel diode can be formed on the Zener diode layered structure. For example, each of the channel diodes include a common N-epitaxial (NEPI) layer and separate P-well regions. The NEPI layer shared by the channel diodes can disposed on the NBL layer of the Zener diode. This provides a path for positive ESD discharges. Other N-well regions can also be implanted on the NEPI layer to form discharge diodes that provide an alternative discharge path for signals having an opposite polarity from the ESD signals that travel in the ESD path through the channel and Zener diodes.

By constructing the channel diodes vertically on top of a common Zener diode substrate layer, semiconductor circuit area can be conserved since a separate lateral area (lateral to channel diode array) on the semiconductor device for the Zener is no longer needed along with corresponding thick signal traces to couple the Zener to the respective channel diode array. The vertical layer structure facilitates compact vertical stacking between the channel diodes and a common Zener which generates minimal power with same level of ESD protection as other circuit designs. Compact vertical stacking also provides the shortest current path for ESD discharge and therefore reduces dynamic resistance of the path. Isolation trenches between channel and discharge diodes in the vertical layer structure can be provided to confine ESD current flows in a vertical direction in the semiconductor device while mitigating leakage paths. The N-EPI and NBL layer selections can be doped such that the parasitic interactions between different channel diodes and/or between the Zener diode and the channel diodes are mitigated. By sharing the Zener across a common layer of the semiconductor device, this reduces use of NBL material, which mitigates out-gassing effects related to NBL regions of the semiconductor device during manufacturing.

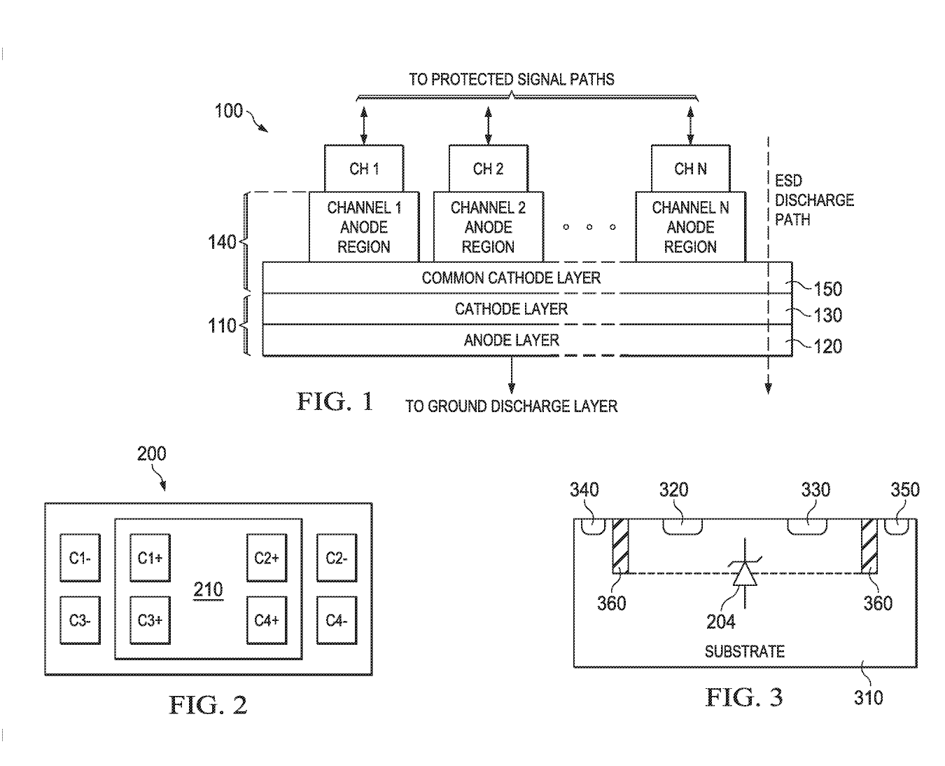

FIG. 1 illustrates an example block diagram of a semiconductor device 100 having a vertical layer Zener structure to provide electrostatic discharge protection for a circuit. As used herein, the term circuit can include a collection of active and/or passive elements that perform a circuit function such as an analog circuit or control circuit, for example. Additionally or alternatively, the term circuit can include an integrated circuit where all the circuit elements are fabricated on a common substrate, for example. The semiconductor device 100 includes a Zener diode, shown at 110, having an anode layer 120 and a cathode layer 130. The Zener diode 110 provides an electrostatic discharge (ESD) path for ESD signals appearing on protected signal paths for a circuit not shown (See, e.g., FIG. 5). At least two channel diodes 140 the ESD signals to the ESD path of the Zener diode 110. The channel diodes 140 include a common cathode layer 150 and a separate anode region for each of the channel diodes. The separate anode regions are shown as Channel 1 anode region, Channel 2 Anode region, Channel N anode region, where N is a positive integer.

The common cathode layer 150 of the channel diodes 140 is disposed on the cathode layer 130 of the Zener diode 110. A separate channel, shown as channels CH1 though CHN is disposed on the separate anode regions of each of the channel diodes 140 to provide a connection to the protected signal paths. In one example, the anode layer 120 of the Zener diode 110 is a P-doped substrate layer of the semiconductor device 100. The cathode layer 130 can be an N-doped buried layer (NBL) that is ion implanted on to the anode layer 120, for example. In some cases parasitic vertical leakage paths can be formed between the channel diodes 140 and the Zener diode 110. To control such leakage paths, the doping level of the NBL layer at 130 can be controlled within a range of about 1E17 to about 2E18 per cubic centimeter of the NBL to mitigate vertical parasitic leakage paths between the channel diodes 140 and the Zener diode 110. The common cathode layer 150 can be grown as an N-doped epitaxial layer (NEPI) on to the cathode layer 130 of the Zener diode 110. To control lateral leakage paths between channel diodes, the doping level of the NEPI layer can be doped such that the resistivity range of the NEPI layer is in a range of about 1 to about 100 ohms per centimeter for the NEPI layer to mitigate lateral parasitic leakage paths between the channel diodes. Also, the lateral distance between the channel diodes can be increased to mitigate parasitic leakage current on the parasitic leakage paths to below a predetermined threshold current. For example, different test semiconductor lots produced with varying lateral distance between channel diodes 140, a distance can be selected between the test lots having a threshold current below the desired threshold value.

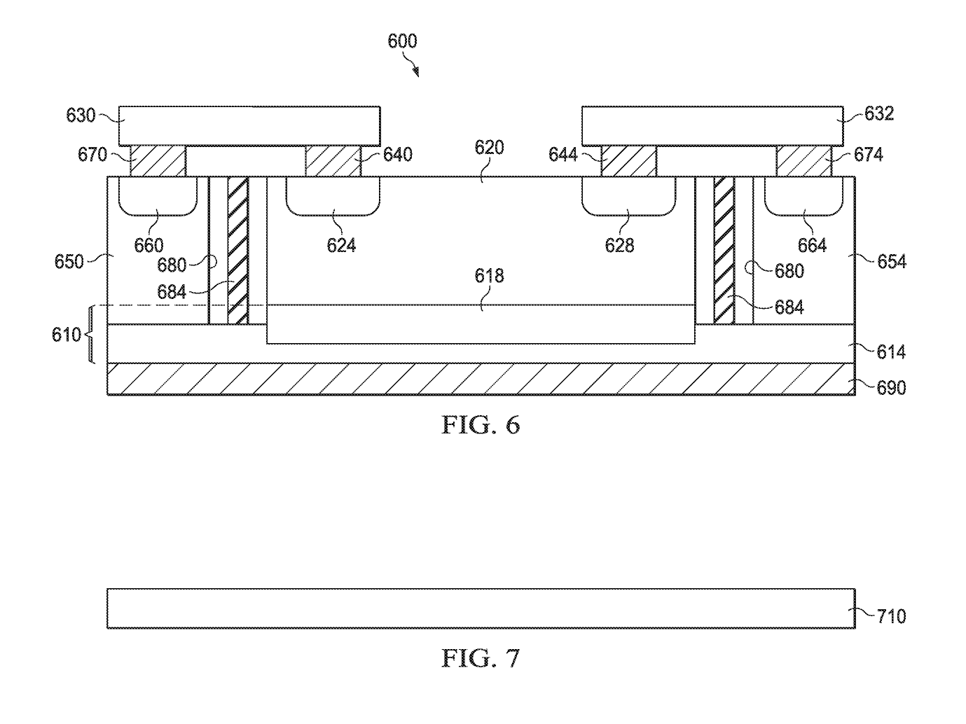

The separate anode regions of the channel diodes 140 can be formed as ion-implanted P-wells, for example. As will be illustrated and described below with respect to FIG. 6, the common cathode layer and 150 can be extended to provide a separate discharge diode coupled to each of the separate channel diodes 140 and disposed on the cathode layer 130 of the Zener diode 110 to provide a discharge path for opposite polarity ESD signals. Further, an isolation trench can be formed between the separate discharge diodes and the channel diodes to isolate parasitic paths between the respective diodes (See e.g., FIG. 6). Although not shown, a metal layer can be disposed beneath the anode layer 120 of the Zener diode 110 to provide a ground path for the ESD signals. The metal layer can be added as a post-production semiconductor process after the other respective layers as described herein have been formed.

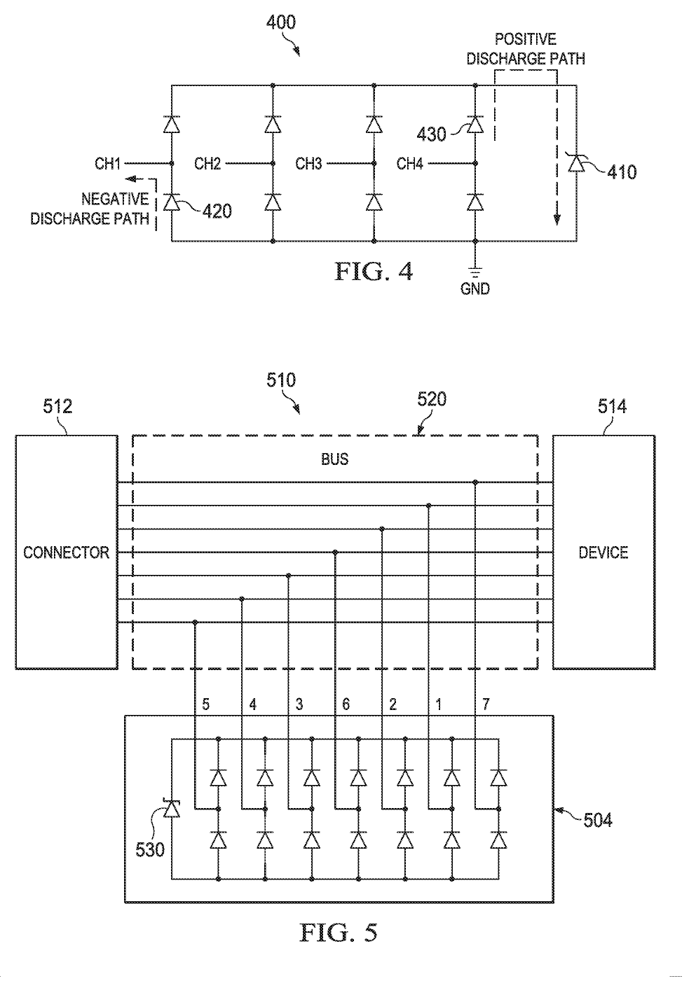

FIG. 2 illustrates an example top view of a semiconductor device 200 having a vertical layer Zener structure to provide electrostatic discharge protection for a circuit. In this example, since a vertical Zener cannot be viewed from the top view, a Zener 204 is symbolically represented in the side view of device 300 of FIG. 3. The device 200 includes four channels for providing signal protection for four signals however more or less than four channels can be provided. The channels are represented as diode pairs and shown as pair C1+/C1−, C2+/C2−, C3+/C3−, and C4+/C4−. The positive labeled channels are for positive ESD discharges with respect to ground and the negative labeled channels are for negative ESD discharges with respect to ground. For positive discharge currents, the Zener 204 is in series with the positive labeled channels to raise the threshold breakdown voltage of the protected signal path. A schematic diagram of the respective channel pairs is shown and described below with respect to FIG. 4. An isolation trench 210 can be formed between the positive and negative channel diodes to cause force ESD current paths in a vertical direction and to mitigate lateral leakage current flows between the positive labeled channels and their respective negative channel counterparts.

FIG. 3 illustrates an example side view of a semiconductor device 300 having a vertical layer Zener structure to provide electrostatic discharge protection for a circuit. As described above, a Zener 204 is formed on a substrate 310 and provides an ESD current path for positive channels shown at 320 and 330. Negative current paths can travel though diodes 340 and 350 thus bypassing the Zener 204. An isolation trench 360 illustrates a cutaway side view of the isolation trench 210 described above with respect to FIG. 2.

FIG. 4 illustrates an example circuit diagram of a semiconductor ESD protection device 400. In this example, the ESD protection device 400 includes having a vertical layer Zener structure to provide electrostatic discharge protection for a circuit. In this example, the vertical Zener structure described herein is shown at 410. A channel diode array having four channels is shown with each channel labeled as CH1, CH2, CH3, and CH4. If a negative ESD discharge were to occur on channel CH1 for example, an example negative discharge current path is shown that flows though diode 420 of CH1 to ground. If a positive ESD discharge were to occur such as shown on channel CH4, a positive discharge current would flow though diode 430 of CH4 though the Zener 410 to ground. Similar discharge paths for channels CH2 and CH3 are not described for purposes for brevity. As noted above, more or less than four channels (e.g., two channel device) sharing a common Zener in a vertical layer structure can be provided as described herein.

The device 400 thus operates as a passive integrated circuit that activates in response to input voltages above a breakdown voltage or below the forward bias voltage of lower diodes 420. High voltages that can occur during ESD events (e.g., as high as ±15 kV) can be directed to ground via the internal diode network. Once the voltages on the protected line fall below the trigger levels of the device the device reverts to passive.

FIG. 5 illustrates an example a semiconductor device 504 having a vertical layer Zener structure to provide electrostatic discharge protection for a bus communications circuit 510. In this example, two devices shown as connector 512 and Device 514 communicate across a bus 520. The bus 520 includes seven signal lines (e.g., address, data, or serial lines) which are protected by the device 504 having seven channels of protection. Each channel of the device 504 includes a pair of series connected diodes to route positive and/or negative ESD signals as described above with respect to FIG. 4. The series connected diodes of each channel is disposed on top of a vertical layered Zener 530 to provide clamping for positive ESD signals at a desired minimum threshold to avoid conflicts with the signals on the seven protected signal lines on the bus 520.

FIG. 6 illustrates an example semiconductor device structure 600 having a vertical layer Zener structure to provide electrostatic discharge protection for a circuit. The semiconductor device structure 600 includes a Zener diode 610 having a P substrate layer 614 and an N buried layer (NBL) 618 implanted on the P substrate layer (e.g., ion implantation). The Zener diode 614 provides an electrostatic discharge (ESD) path for ESD signals appearing on protected signal paths. At least two channel diodes couple the ESD signals to the ESD path of the Zener diode 610. The channel diodes include a common N-epitaxial (NEPI) layer 620 and a separate P-well region 624 and 628 for each of the channel diodes. The common NEPI layer 620 of the channel diodes is disposed on the NBL layer 618 of the Zener diode 610. A separate channel 630 and 632 is disposed on the separate P-well regions 624 and 628 of each of the channel diodes to provide an electrical connection to respective protected signal paths. Coupling contacts 640 and 644 couple the channels 630 and 632 to the P-well regions 624 and 628.

The NEPI layer 620 can be extended over the P substrate layer 614 to provide NEPI regions 650 and 654. N wells 660 and 664 can be provided to form opposite polarity diodes formed with the P substrate layer 614 and NEPI regions 650 and 654 to provide a negative discharge path as described herein. The N wells 660 and 664 can be coupled via coupling contacts 670 and 674 to the respective channels 630 and 632. An isolation trench 680 can be etched into the NEPI layer 620 and the NEPI regions 650 and 654 to provide isolation between the positive discharge channel diodes and the negative discharge channel diodes described herein. The isolation trench 684 can be filled with oxide and poly-silicon, for example, to increase the voltage breakdown capability of the trench.

A metal layer 690 can be deposited on the P substrate layer as a post-production process to provide a ground path for the P substrate layer and to enable ESD signals to discharge. As noted previously, the doping level of the NBL layer 618 can be controlled within a range of about 4E17 to about 2E18 per cubic centimeter of the NBL layer to mitigate vertical parasitic leakage paths between the channel diodes and the Zener diode 610. Also, the doping level of the NEPI layer 620, 650, and 654 can be doped such that the resistivity range of the NEPI layer is in a range of about 10 to about 60 ohms per centimeter for the NEPI layer to mitigate lateral parasitic leakage paths between the channel diodes.

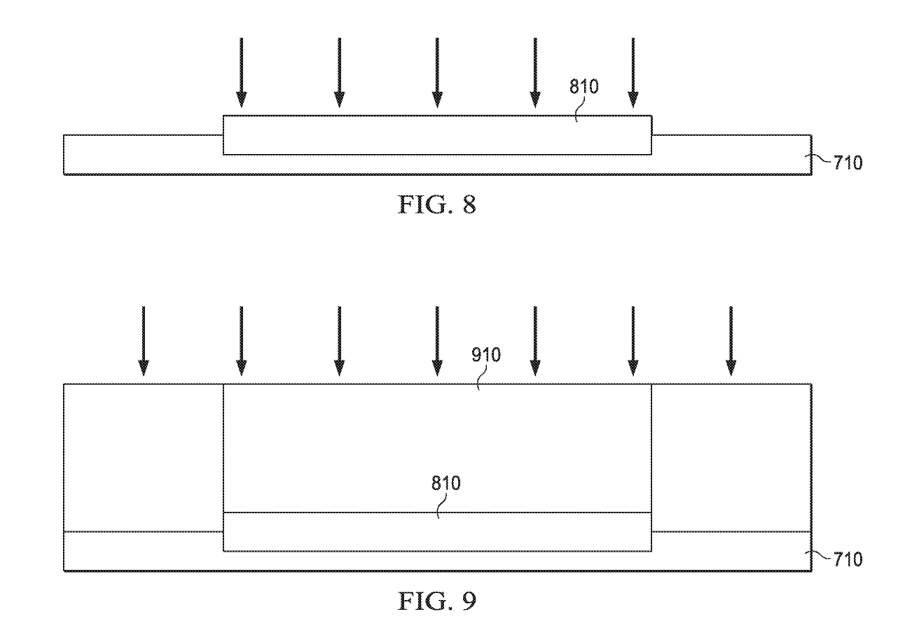

In view of the foregoing structural and functional features described above, an example method will be better appreciated with reference to FIGS. 7-13. While, for purposes of simplicity of explanation, the method shown in FIGS. 7-13 and described as executing serially, it is to be understood and appreciated that the method is not limited by the illustrated order, as parts of the method could occur in different orders and/or concurrently from that shown and described herein. Such method can be executed by various components in a semiconductor manufacturing process, for example, including silicon growing techniques, ion implantation, chemical or vapor deposition, resist applications for masking, and etching.

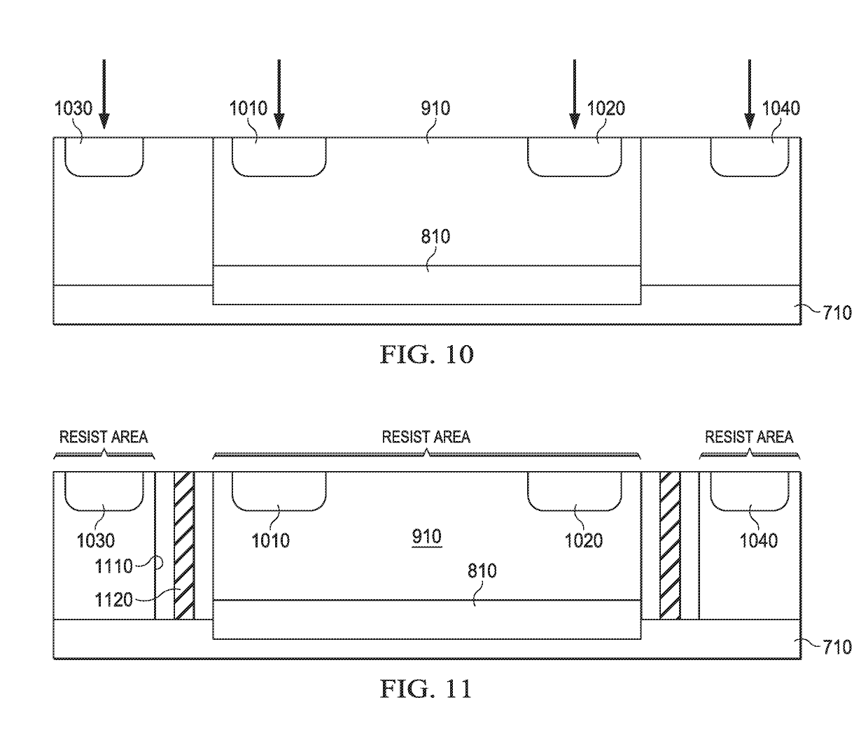

FIGS. 7-13 illustrate an example method for manufacturing the semiconductor device of FIG. 6. FIGS. 7-13 are collectively describe an example manufacturing process however some of the processes shown may occur out of order of the process sequence described herein. FIG. 7 of the method described herein shows forming a P substrate layer 710 for a semiconductor device. This layer 710 can be acquired as a starting layer from a semiconductor vendor, for example. FIG. 8 of the method shows disposing an N buried layer (NBL) 810 (e.g., via ion implantation) on the P substrate layer 710 to form a Zener diode with the P substrate layer. FIG. 9 of the method shows forming an N-epitaxial (NEPI) layer 910 on the NBL layer 810 and the P substrate layer 710 to from a common cathode layer for at least two channel diodes. FIG. 10 of the method shows forming a separate P-well 1010 and 1020 on the NEPI layer 910 to form the channel diodes on the NEPI layer. This includes forming a separate N-well 1030 and 1040 on the NEPI layer 910 to form opposite polarity diodes from the channel diodes on the NEPI layer and the P substrate layer 710.

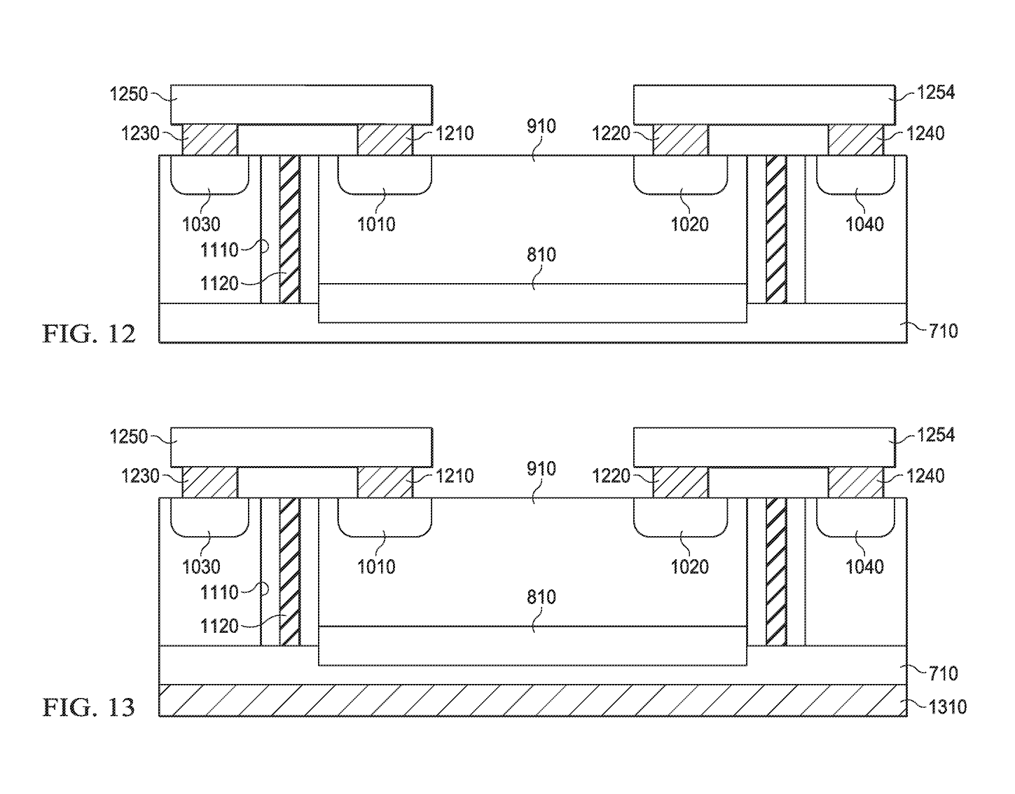

FIG. 11 illustrates an example of how the isolation trenches are formed as described herein. First, a resist material is applied to resist regions of the NEPI layer. The method then includes forming an isolation trench 1110 in the NEPI layer 910 and the NBL layer 810 to provide isolation between the channel diodes and the opposite polarity channel diodes. The method can include filling the isolation trench 1110 with oxide and poly-silicon at 1120 to increase the voltage breakdown capability of the trench. FIG. 12 of the method shows depositing a contact connection 1210 and 1220 on the separate P-wells 1010 and 1020 and contact connections 1230 and 1240 on N-wells 1030 and 1040, respectively. The method includes bonding a channel 1250 and 1254 to connect P-well and N-well pairs to provide a connection point for a signal protection path. FIG. 13 of the method shows forming a metallic layer 1310 underneath the P substrate layer 710 to provide a ground path for the substrate layer. The methods described herein can include doping the NBL layer within a range of about 1E17 to about 2E18 per cubic centimeter of the NBL layer to mitigate vertical parasitic leakage paths between the channel diodes and the Zener diode. The method can include doping the NEPI layer 910 such that the resistivity range of the NEPI layer is in a range of about 1 to about 100 ohms per centimeter for the NEPI layer to mitigate lateral parasitic leakage paths between the channel diodes.

What have been described above are examples. It is, of course, not possible to describe every conceivable combination of components or methodologies, but one of ordinary skill in the art will recognize that many further combinations and permutations are possible. Accordingly, the disclosure is intended to embrace all such alterations, modifications, and variations that fall within the scope of this application, including the appended claims. As used herein, the term “includes” means includes but not limited to, the term “including” means including but not limited to. Additionally, where the disclosure or claims recite “a,” “an,” “a first,” or “another” element, or the equivalent thereof, it should be interpreted to include one or more than one such element, neither requiring nor excluding two or more such elements.

What is claimed is:

1. A semiconductor device comprising:
a Zener diode comprising an anode layer and a cathode layer, the Zener diode provides an electrostatic discharge (ESD) path for ESD signals;
at least two channel diodes coupled to the ESD path of the Zener diode, each of the channel diodes includes a common cathode layer and a separate anode region, the common cathode layer of the channel diodes being disposed on the cathode layer of the Zener diode; and
at least two channels, each channel coupled to one of the separate anode regions to provide an electrical connection for protected signal paths to the ESD path.

2. The semiconductor device of claim 1, wherein the anode layer of the Zener diode is a P-doped substrate layer.

3. The semiconductor device of claim 2, wherein the cathode layer is an N-doped buried layer (NBL) that is ion implanted on the anode layer.

4. The semiconductor device of claim 3, wherein a doping level of the NBL is within a range of about 1E17 to about 2E18 per cubic centimeter of the NBL to mitigate vertical parasitic leakage paths between the channel diodes and the Zener diode.

5. The semiconductor device of claim 1, wherein the common cathode layer is grown as an N-doped epitaxial layer (NEPI) on to the cathode layer of the Zener diode.

6. The semiconductor device of claim 5, wherein a doping level of the NEPI layer is doped such that the resistivity range of the NEPI layer is in a range of about 1 to about 100 ohms per centimeter for the NEPI layer to mitigate lateral parasitic leakage paths between the channel diodes.

7. The semiconductor device of claim 6, wherein a lateral distance between the channel diodes is increased to mitigate parasitic leakage current on the parasitic leakage paths to below a predetermined threshold current.

8. The semiconductor device of claim 1, wherein the separate anode regions of the channel diodes are formed as respective P-wells.

9. The semiconductor device of claim 1, further comprising a respective discharge diode coupled between one of the at least two channels and the cathode layer of the Zener diode to provide another discharge path for protected signals at each channel having an opposite polarity from the ESD signals to travel in the ESD path.

10. The semiconductor device of claim 9, further comprising an isolation trench between the separate discharge diodes and the channel diodes to isolate parasitic paths between the respective discharge diodes and the channel diodes.

11. The semiconductor device of claim 1, further comprising a metal layer disposed beneath the anode layer of the Zener diode to provide a ground path for the ESD signals.

12. A semiconductor device comprising:
a Zener diode comprising a P substrate layer and an N buried layer (NBL) disposed on the P substrate layer, the Zener diode provides an electrostatic discharge (ESD) path for ESD signals;
at least two channel diodes to couple the ESD signals to the ESD path of the Zener diode, the channel diodes include a common N-epitaxial (NEPI) layer and a separate P-well region for each of the channel diodes, the common NEPI layer of the channel diodes disposed on the NBL of the Zener diode; and
at least two channels, each channel coupled to the P-well region of one of the channel diodes to provide an electrical connection for protected signal paths to the ESD path.

13. The semiconductor device of claim 12, wherein a doping level of the NBL is within a range of about 1E17 to about 2E18 per cubic centimeter to mitigate vertical parasitic leakage paths between the channel diodes and the Zener diode, and
wherein a doping level of the NEPI layer is doped such that the resistivity range of the NEPI layer is in a range of about 1 to about 100 ohms per centimeter to mitigate lateral parasitic leakage paths between the channel diodes.

14. The semiconductor device of claim 12, further comprising:
a discharge diode between one of the at least two channels and the NBL of the Zener diode to provide a discharge path for the ESD signals having an opposite polarity from the ESD signals to travel in the ESD path; and
an isolation trench between the discharge diodes and the channel diodes to isolate parasitic paths between the respective discharge diodes and the channel diodes.

15. The semiconductor device of claim 12, further comprising a metal layer disposed beneath the P substrate layer of the Zener diode to provide a ground path for the ESD signals.

16. A method comprising:
forming a P substrate layer;
disposing an N-buried layer (NBL) on the P substrate layer to form a Zener diode in which the P substrate layer is an anode layer and the NBL is a cathode layer;
forming an N-epitaxial (NEPI) layer on the NBL;
forming at least two P-well regions in the NEPI layer to provide at least two channel diodes in which the NEPI layer provides a common cathode layer for each of the at least two channel diodes;
forming a separate N-well region in the NEPI layer to provide at least one discharge diode that includes the N-well region and the P substrate layer; and
forming an isolation trench through the NEPI layer and the NBL between the channel diodes and the discharge diodes.

17. The method of claim 16, further comprising:
depositing a contact connection on each P-well and N-well region; and
bonding a channel to connect P-well and N-well pairs to couple each discharge diode with a respective channel diode and provide a connection for a signal protection path.

18. The method of claim 16, further comprising filling the isolation trench with oxide and poly-silicon to increase the voltage breakdown capability of the trench.

19. The method of claim 16, further comprising applying a metal layer beneath the P substrate layer to provide a ground path for the P substrate layer.

20. The method of claim 16, further comprising:
doping the NBL with an N+ dopant in a range from about 1E17 to about 2E18 per cubic centimeter to mitigate vertical parasitic leakage paths between the channel diodes and the Zener diode; and
doping the NEPI layer such that the resistivity range of the NEPI layer is in a range of about 1 to about 100 ohms per centimeter to mitigate lateral parasitic leakage paths between the channel diodes.
